(19) United States
(12) Patent Application Publication
(10) Pub. No.: US 2011/0100442 A1
(43) Pub. Date: May 5, 2011

(54) Structure of a Solar Cell

(75) Inventors: Jian-Jang Huang, Taipei City (TW); Cheng-Pin Chen, Nanjhou Township (TW); Pei-Hsuan Lin, Taipei City (TW)

(73) Assignee: NATIONAL TAIWAN UNIVERSITY, Taipei City (TW)

(21) Appl. No.: 12/870,248

(22) Filed: Aug. 27, 2010

(30) Foreign Application Priority Data
Oct. 29, 2009 (TW) 98136670

(51) Int. Cl. H01L 31/04

(52) U.S. Cl. 136/255; 136/252

(57) ABSTRACT

A structure of a solar cell. The structure of the solar cell includes a substrate, a graded layer and a semiconductor layer. The graded layer is disposed on the substrate. The graded layer is made from materials including the first material and the second material, and includes at least one thin film. One of the at least one thin film includes a mixture of at least the first material and the second material at a mixture ratio. The mixture forms a bandgap of the at least one thin film. The semiconductor layer is disposed on the graded layer.

This application claims the benefit of Taiwan application Serial No. 98136670, filed Oct. 29, 2009, the subject matter of which is incorporated herein by reference.

### BACKGROUND OF THE INVENTION

1. Field of the Invention

The invention relates in general to a structure of a solar cell, and more particularly to a structure of a solar cell with a graded layer.

2. Description of the Related Art

Due to the energy crisis, the whole world is engaged in the pursuit of all sorts of alternative energy sources. Of the alternative energy sources with great development potential such as hydraulic power, wind power, solar power, terrestrial heat, sea water, temperature difference, waves, and tides, the solar power has become a mainstream of the new energy sources. According to estimation, the energy that the sun illuminated on the surface of the earth per year is one million times of the energy annually consumed by people on the earth. If 1% of the inexhaustible energy of solar light can be converted into electric power by solar cells, the generated energy will suffice to meet people's needs of energy.

The conventional solar cells available now in the market can convert the energy of the solar light into electrical energy. However, the efficiency of photoelectric conversion is not satisfactory. The solar light has a wide spectral range, but the conventional solar cells can convert only a portion of the spectral range of the solar light into electrical energy.

### SUMMARY OF THE INVENTION

The invention is directed to a structure of a solar cell, wherein its light absorption rate can be increased by adjusting the mixture ratio of the thin films included in the graded layer of the solar cell.

According to a first aspect of the present invention, a structure of a solar cell is provided. The structure of the solar cell includes a substrate, a graded layer, and a semiconductor layer. The graded layer is disposed on the substrate. The graded layer is made from materials including a first material and a second material, and includes at least one thin film. One of the at least one thin film includes a mixture of at least the first material and the second material at a mixture ratio. The mixture forms a bandgap of the at least one thin film. The semiconductor layer is disposed on the graded layer.

According to a second aspect of the present invention, a structure of a solar cell is provided. The structure of the solar cell includes a substrate, a first semiconductor layer, a graded layer, and a second semiconductor layer. The first semiconductor layer is disposed on the substrate. The graded layer is disposed on the first semiconductor layer and made from materials including a first material and a second material. The graded layer includes at least one thin film. One of the at least one thin film includes a mixture of at least the first material and the second material at a mixture ratio. The mixture forms a bandgap of the at least one thin film. The second semiconductor layer is disposed on the graded layer.

The above and other aspects of the invention will become better understood with regard to the following detailed description of the preferred but non-limiting embodiments. The following description is made with reference to the accompanying drawings.

### BRIEF DESCRIPTION OF THE DRAWINGS

FIG. 1 shows a sectional view of a solar cell according to a first embodiment of the invention.

FIG. 2A shows a schematic diagram of an example of the solar cell of FIG. 1.

FIG. 2B shows a schematic diagram of an example of the solar cell of FIG. 1.

FIG. 3 is a diagram illustrating bandgap distribution of the graded layer in FIG. 1.

FIG. 4 shows a sectional view of an example of the structure of the solar cell of FIG. 1 with co-planar electrodes.

FIG. 5 shows a sectional view of an example of the structure of the solar cell of FIG. 1 with bottom-up electrodes.

FIG. 6 shows a sectional view of a solar cell according to a second embodiment of the invention.

FIG. 7 shows a sectional view of an example of the solar cell of FIG. 6.

FIG. 8 shows a sectional view of an example of the solar cell of FIG. 6.

### DETAILED DESCRIPTION OF THE INVENTION

### First Embodiment

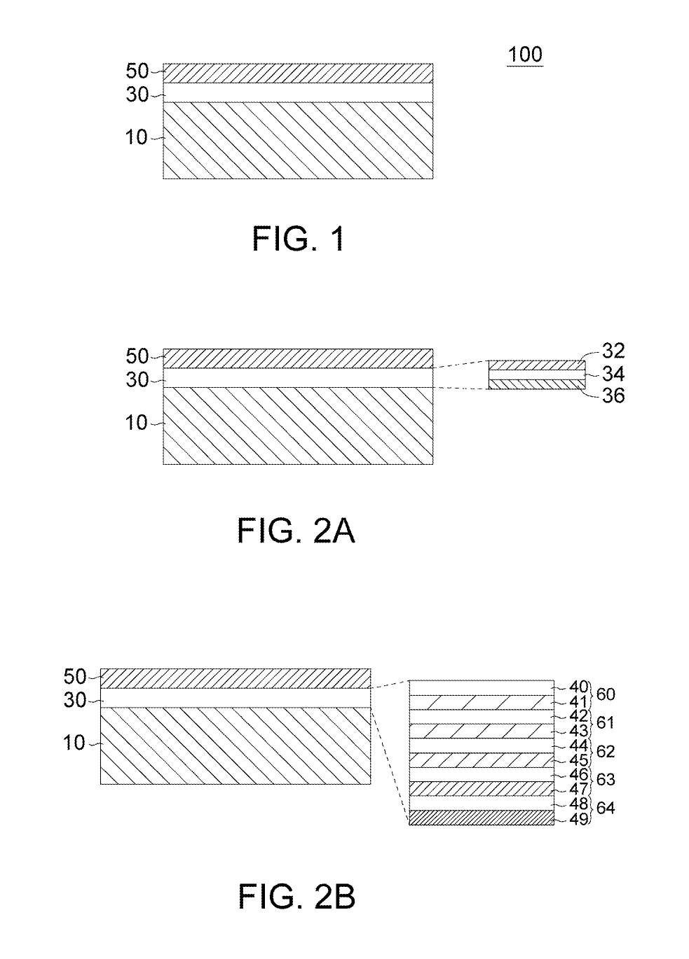

Referring to FIG. 1, a sectional view of a solar cell according to the first embodiment of the invention is shown. The structure of the solar cell 100 includes a substrate 10, a graded layer 30, and a semiconductor layer 50.

The graded layer 30 is disposed on the substrate 10 and made from materials including a first material and a second material. The graded layer 30 includes at least one thin film. One of the at least one thin film includes a mixture of the first material and the second material at a mixture ratio and the mixture forms a bandgap of the at least one thin film. The semiconductor layer 50 is disposed on the graded layer 30.

The substrate 10 can be made from a low bandgap semiconductor material, such as an N-type or P-type material, and the semiconductor layer 50 can be made from a high bandgap semiconductor material, such as a P-type of N-type material. In another embodiment, the substrate 10 can be made from an N-type high bandgap semiconductor material, and the semiconductor layer 50 can be made from a P-type low bandgap semiconductor material. In other examples, the substrate 10 and the semiconductor layer 50 can be made from a high bandgap semiconductor material and a low bandgap semiconductor material respectively. Nevertheless, any solar cell can be employed for the implementation of the solar cell 100 if the junction of the substrate 10 and the semiconductor layer 50 forms a P-N junction according to the theory of the solar cell so as to achieve photoelectric conversion when the light is illuminated on the solar cell.

The first material is a metal oxide or semiconductor material, and the second material is also a metal oxide or semiconductor material. The mixture ratio of the first material and the second material is related to the desired bandgap. In this way, the mixtures at different mixture ratios can be made to correspond to different bandgaps. Relatively, a mixture can be realized by a metal oxide material, or several metal oxide materials or a combination of a metal oxide material and a semiconductor material. Thus, in practical application, the bandgap of the graded layer can be designed flexibly according to the target wavelength of the solar light.

Furthermore, the oxide semiconductor can be realized by zinc oxide (ZnO). The metal material can be realized by aluminum (Al), germanium (Ge), indium (In) or mengan (Mg). The metal oxide material can be realized by or includes at least one of titanium dioxide (TiO₂), indium oxide (InO), indium tin oxide (ITO), manganese oxide (MgO), tin dioxide (SnO₂), germanium dioxide (GeO₂), aluminum oxide (Al₂O₃), tantalum oxide (TaO₅), cupric oxide (CuO) or zirconium dioxide (ZrO₂). The metal oxide material can also be the combination of two of more of the above materials.

For example, the bandgap of the graded layer 30 is determined according to the following formula:

Eg=XEgl+(1−X)Eg2−X(1−X)c; (formula 1)

wherein Eg1 indicates the bandgap corresponding to the first material; X denotes the mixture ratio of the first material and the second material; Eg2 indicates the bandgap corresponding to the second material; Eg denotes the corresponding bandgap of the mixture of the first material and the second material at a mixture ratio; and c denotes a constant corresponding to the material.

In another example, the graded layer 30 has several layers of thin films, and has several bandgaps, wherein each layer of thin films includes a mixture of the first material and the second material at a corresponding mixture ratio, and the mixtures respectively form the corresponding bandgaps of the thin films. For example, a mixture of the first material and the second material at a mixture ratio forms a bandgap of the thin film. Accordingly, the several layers of thin films respectively corresponding to different mixtures of the first material and the second material at different mixture ratios form the bandgaps of the thin films corresponding to the mixtures. In other words, the layers of thin films respectively having different mixtures of the first material and the second material at different mixture ratios implies that the thin films have several bandgaps for absorbing the solar light with broader frequency spectrum, thus increasing the photoelectric conversion efficiency of the solar cell. An example is exemplified below.

Referring to FIG. 2A, a schematic diagram of an example of the solar cell of FIG. 1 is shown. In an embodiment, it is assumed that the graded layer 30 has several thin films 32-36 each including a mixture of the first material and the second material at a corresponding mixture ratio. The mixtures form several bandgaps corresponding to the thin films 32-36. That is, by adjusting the mixture ratio at which the first material and the second material are mixed in the thin film, the bandgap corresponding to the thin films is changed accordingly.

For example, the corresponding bandgaps of the thin film can be realized by a graded energy bandgap. That is, the graded energy bandgap can absorb the solar light with corresponding wavelength, and convert the energy of the solar light within the wide spectral range into electrical energy so as to increase the efficiency in photoelectric conversion.

Besides, the magnitude of the bandgaps of the graded layer 30 ranges between the magnitude of the bandgap of the substrate 10 and that of the semiconductor layer 50. In greater details, the magnitude of the graded energy bandgap gradually increases with distance away from the substrate 10 to the semiconductor layer 50, and the graded energy bandgap, for example, ranges from 1.0 to 4.0 electronic volts (eV). Apart from the example of the thin films 32-36 disclosed above, in other embodiments, the number of the thin films can be determined according to the application of the solar cell, and the bandgap of the thin film can further be designed according to the target light source for increasing the absorption rate of the light. The arrangement of bandgap of the materials forming the substrate 10, the graded layer 30 and the semiconductor layer 50 can have various implementations and will be exemplified below.

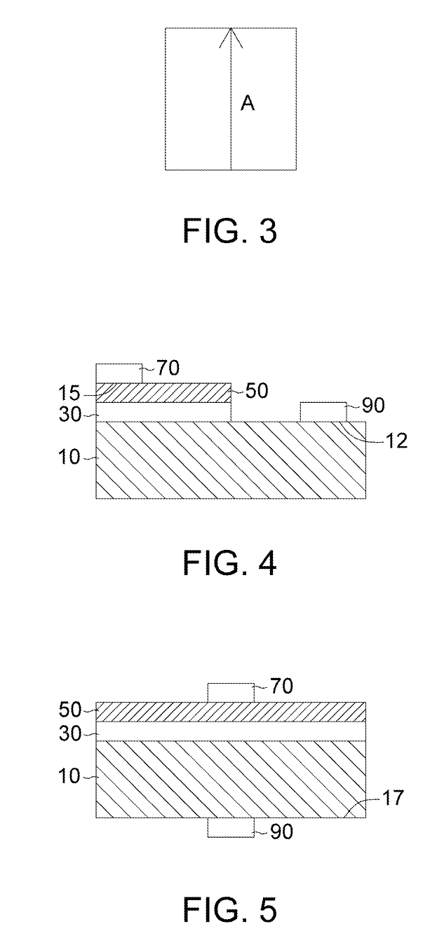

Referring to FIG. 3, a diagram illustrates the bandgap distribution of the graded layer of FIG. 1. In an implementation, the substrate 10 is made from a low bandgap semiconductor material; the semiconductor layer 50 is made from a high bandgap semiconductor material. In addition, the magnitude of the bandgap of the graded layer 30 increases along the direction of the arrow A. In another implementation, it is assumed that the substrate 10 is made from a high bandgap semiconductor material, and the semiconductor layer 50 is made from a low bandgap semiconductor material. In addition, the magnitude of the bandgap of the graded layer decreases along the direction of the arrow A.

Referring to FIG. 2B, a schematic diagram of an example of the solar cell of FIG. 1 is shown. In an implementation, presumable, the graded layer 30 is a super lattice layer, which includes a plurality of thin film groups, wherein each thin film group includes a first and a second thin film and corresponds to a bandgap. For example, the bandgap is a energy bandgap and ranges between the bandgap of the substrate 10 and that of the semiconductor layer 50. The bandgap (that is, the energy bandgap) corresponding to several thin film groups can also absorb the solar light with corresponding wavelengths and converts the energy of the solar light within the wide spectral range into electrical energy so as to increase the efficiency in photoelectric conversion.

For example, the graded layer 30 (that is, the super lattice layer) includes five thin film groups 60-64 each including first thin films 40, 42, 44, 46, 48 and second thin films 41, 43, 45, 47, 49. The substrate 10 is made from a high bandgap semiconductor material and the semiconductor layer 50 is made from a low bandgap semiconductor material. In addition, the first thin films 40-48 of each thin film group are made from a high bandgap semiconductor material, and the second thin films 41-49 of each thin film group are made from a low bandgap semiconductor material. That is, the corresponding energy bandgap of the graded layer 30 (that is, super lattice layer) alternates between high and low bandgap levels and substantially decreases along the direction of the arrow A (referring to FIG. 3).

In another implementation, the substrate 10 is made from a low bandgap semiconductor material, and the semiconductor layer 50 is made from a low bandgap semiconductor material. In addition, the first thin films 40-48 of each thin film group are made from a low bandgap semiconductor material, and the second thin films 41-49 of each thin film group are made from a high bandgap semiconductor material. That is, the corresponding energy bandgap of the graded layer 30 (that is, super lattice layer) alternates between high and low bandgap levels and substantially increases along the direction of the arrow A (referring to FIG. 3).

For example, the graded layer 30 is a super lattice layer implemented through metal organic chemical vapor deposition (MOCVD) or molecular beam epitaxy (MBE). The super lattice layer has superior absorption characteristics, and the wavelength absorbable to the super lattice layer can be designed according to target wavelengths to be absorbed. That is, the object of converting the energy of the light with target wavelength into electrical energy can be achieved by replacing expensive substrate such as gallium arsenide (GaAs) substrate with cheaper substrate such as silicon (Si) substrate.

Besides, the structural characteristics of the super lattice layer enable the solar cell using the same to maintain stability when operating under high temperature. That is, the operation characteristics of the super lattice layer have little change (for example, the shift in the absorbable wavelength corresponding to each thin film group). Also, the number of the thin film included in the super lattice layer can be designed and adjusted according to the user's needs and the conditions of the application, and is not limited to the above exemplification.

In practical application, the disposition of electrodes depends on the structure of the solar cell of FIG. 1. FIG. 4 shows a sectional view of an example of the structure of the solar cell of FIG. 1 with co-planar electrodes. In practical application, there are many implementations for disposing the electrodes on the solar cell 100. In FIG. 4, an implementation illustrates that a portion 12 of the substrate 10 extends over the semiconductor layer 50 so that the electrodes, such as the first electrode 70 and the second electrode 90, can be disposed thereon. The first electrode 70 is disposed on a portion of the semiconductor layer 50, such as on a portion of an upper surface 15 of the semiconductor layer 50. The second electrode 90 is disposed on a portion 12 of the substrate 10.

Referring to FIG. 5, a sectional view of an example of the structure of the solar cell of FIG. 1 with bottom-up electrodes is shown. In an implementation, the second electrode 90 is directly disposed on a lower surface 17 of the substrate 10, and the first electrode 70 is disposed on a portion of the semiconductor layer 50.

In the present embodiment, the oxide semiconductor material (or the high bandgap semiconductor material) can be realized by zinc oxide material

(ZnO), and the low bandgap semiconductor material can be realized by silicon (Si), germanium (Ge) or gallium arsenide (GaAs) material, and can even be at least one material selected from of the group consisting of germanium (Ge), indium (In), aluminum (Al), gallium (As), phosphorous (P) and antimony (Sb), or any other substitute material.

The first electrode and the second electrode can be used for creating Ohm contacts with the semiconductor layer and the substrate respectively. The first electrode 70 is made from the materials including titanium (Ti) and gold (Au) for example. The second electrode 90 is made from the materials including nickel (Ni) and gold (Au) for example. Other implementations of materials and positions for creating Ohm contacts with the semiconductor layer and the substrate (such as the implementation of the back electrode illustrated in FIG. 5) are also applicable to the first electrode and the second electrode.

In the present embodiment, there are many implementations for manufacturing the mixture of the first material and the second material at a mixture ratio. In an implementation, the first material can be realized by zinc oxide (ZnO) material, the second material can be realized by indium oxide material (InO), and the graded layer 30 is formed by a sputtering process.

For example, indium oxide and zinc oxide are utilized to form the graded layer 30 by way co-sputtering process so that the graded layer 30 has several bandgaps. During the manufacturing process, the mixture ratio of indium oxide and zinc oxide is determined by adjusting the power applied to the target material including indium oxide and zinc oxide, so that the graded layer 30 has several bandgaps for absorbing the energy of the solar light within the wide spectral range. Thus, the structure of the solar cell 100 of the present embodiment can be applied to effectively increase the efficiency in photoelectric conversion. In other implementation, during the sputtering process, the variety of process gas can be selected and the flow of the process gas can be adjusted, so as to determine the mixture ratio of the first material and the second material.

In the above embodiment, the mixture ratio of the first material and the second material can be determined by way of pulsed laser deposition (PLD), thermal chemical vapor deposition (Thermal CVD), plasma enhanced chemical vapor deposition (PECVD) or metal organic chemical vapor deposition (MOCVD), in order to manufacture the graded layer 30 and the semiconductor layer 50 as well.

### Second Embodiment

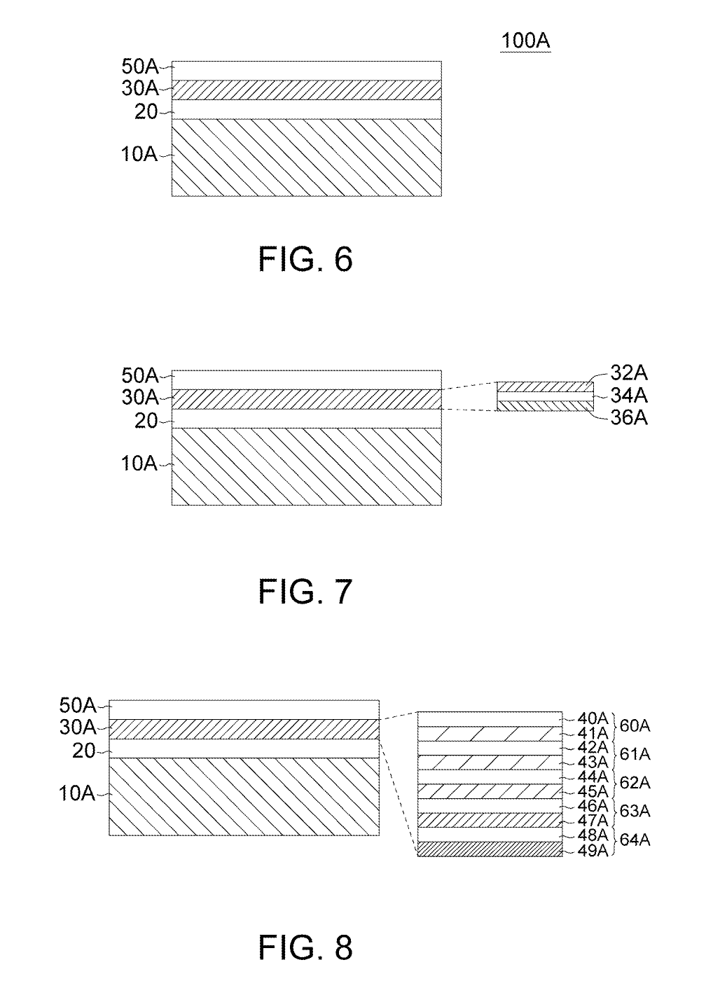

As indicated in FIG. 6, the solar cell 100A of the second embodiment is different from the solar cell 100 of the first embodiment in that: the solar cell 100A includes a substrate 10A, a first semiconductor layer 20, a graded layer 30A and a second semiconductor layer 50A, and a P-N junction is formed by the first semiconductor layer 20 and the second semiconductor layer 50A, and the substrate 10A is made from a transparent material. The similarities will not be described for the sake of brevity. The solar cell of the present embodiment is disclosed below in a block diagram.

Referring to FIG. 6, the first semiconductor layer 20 is disposed on the substrate 10A. The graded layer 30A is disposed on the first semiconductor layer 20, and is made from materials including a first material and a second material. The graded layer 30A includes at least one thin film. One of the at least one thin film includes the mixture of the first material and the second material at a mixture ratio, wherein the mixture forms a bandgap of the at least one thin film. The second semiconductor layer 50A is disposed on the graded layer 30A.

In the present embodiment, the substrate 10A can be made from a transparent material or a soft material. For example, the transparent material can be realized by glass or quartz, and the soft material can be realized by plastics. The substrate 10A can also be made from a semiconductor material.

Referring to FIG. 7, a sectional diagram of an example of the solar cell of FIG. 6 is shown. The graded layer 30A has several thin films, such as thin films 32A-36A. The graded layer 30A is likened to the graded layer 30 of the first embodiment and the other similarities are not repeated here. Also, the magnitude of the bandgaps of the first semiconductor layer 20, the graded layer 30A and the second semiconductor layer 50A can be designed according to the magnitude of the bandgap of the substrate 10A.

Referring to FIG. 8, a schematic diagram of an example of the solar cell of FIG. 6 is shown. The graded layer 30A is a super lattice layer, which includes a plurality of thin film groups. For example, the super lattice layer (that is, the graded layer 30A) includes five thin film groups 60A-64A wherein the thin film group includes first thin films 40A, 42A, 44A, 46A, 48A respectively and second thin films 41A, 43A, 45A, 47A, 49A respectively. The graded layer 30A is likened to the graded layer 30 of the first embodiment, and thus the other similarities are not repeated here.

In the present embodiment, the first semiconductor 20 is made from a low bandgap semiconductor material, such as a P-type material, and the second semiconductor layer 50A is made from a high bandgap semiconductor material, such as an N-type material. The above low bandgap semiconductor material can also be implemented according to the example of the first embodiment, and are not repeated here. As disclosed in the first embodiment, any implementation of the first semiconductor layer 20 and the second semiconductor layer 50A would do if the first semiconductor layer 20 and the second semiconductor layer 50A, after being coupled together, can achieve photoelectric conversion according to the principles of the solar cell.

Apart from converting the energy of the solar light with wide range of wavelengths into electrical energy so as to increase the efficiency in photoelectric conversion, the structure of the solar cell of the present embodiment of the invention can be applied to the substrate made from a soft material or a transparent material so as to achieve a wider range of application.

While the invention has been described by way of examples and in terms of preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A structure of a solar cell, comprising:
a substrate;
a graded layer disposed on the substrate, wherein the graded layer is made from materials comprising a first material and a second material, the graded layer comprises at least one thin film, one of the at least one thin film comprises a mixture of at least the first material and the second material at a mixture ratio, the mixture forms a bandgap of the at least one thin film; and
a semiconductor layer disposed on the graded layer.

2. The structure of the solar cell according to claim 1, wherein the graded layer comprises a plurality of thin films with a plurality of corresponding bandgaps of the thin films, each thin film comprises a mixture of the first material and the second material at a corresponding mixture ratio, and the mixtures form the corresponding bandgaps of the thin films.

3. The structure of the solar cell according to claim 2, wherein the substrate is made from a low bandgap semiconductor material, the semiconductor layer is made from a high bandgap semiconductor material, and the graded layer including the thin films has a graded bandgap increasing with distance away from the substrate towards the semiconductor layer.

4. The structure of the solar cell according to claim 2, wherein the substrate is made from a high bandgap semiconductor material, the semiconductor layer is made from a low bandgap semiconductor material, and the graded layer including the thin films has a graded bandgap decreasing with distance away from the substrate towards the semiconductor layer.

5. The structure of the solar cell according to claim 1, wherein the substrate is made from a low bandgap semiconductor material, the semiconductor layer is made from a high bandgap semiconductor material, and the graded layer is made from the materials whose bandgap is greater than that of the substrate and less than that of the semiconductor layer.

6. The structure of the solar cell according to claim 1, wherein the substrate is made from a high bandgap semiconductor material, the semiconductor layer is made from a low bandgap semiconductor material, and the graded layer is made from the materials whose bandgap is less than that of the substrate and greater than that of the semiconductor layer.

7. The structure of the solar cell according to claim 1, wherein one of the substrate and the semiconductor layer is made from a low bandgap semiconductor material, and the other of the substrate and the semiconductor layer is made from a high bandgap semiconductor material.

8. The structure of the solar cell according to claim 1, wherein the graded layer comprises a super lattice layer, the super lattice layer comprises a plurality of thin film groups, each thin film group comprises a first thin film and a second thin film and corresponding to a bandgap.

9. The structure of the solar cell according to claim 8, wherein the substrate is made from a high bandgap semiconductor material, the semiconductor layer is made from a low bandgap semiconductor material, and the graded layer including the thin films has a bandgap alternating between high and low bandgap levels and substantially decreasing away from the substrate towards the semiconductor layer.

10. The structure of the solar cell according to claim 8, wherein the substrate is made from a low bandgap semiconductor material, the semiconductor layer is made from a high bandgap semiconductor material, and the graded layer including the thin films has a bandgap alternating between high and low bandgap levels and substantially increasing away from the substrate towards the semiconductor layer.

11. The structure of the solar cell according to claim 1, further comprising:
a first electrode, disposed on a portion of the semiconductor layer; and
a second electrode, disposed on a portion of an upper surface of the substrate or a lower surface of the substrate.

12. The structure of the solar cell according to claim 1, wherein the first material is made from a metal oxide or semiconductor material, the second material is made from a metal oxide or semiconductor material, and the first and the second materials are of different bandgaps.

13. The structure of the solar cell according to claim 12, wherein the metal oxide material comprises at least one of titanium dioxide (TiO₂), indium oxide (InO), indium tin oxide (ITO), manganese oxide (MgO), tin dioxide (SnO₂), germanium dioxide (GeO₂), aluminum oxide (Al₂O₃), tantalum oxide (TaO₅), cupric oxide (CuO), and zirconium dioxide (ZrO₂).

14. A structure of a solar cell, comprising:
a substrate;
a first semiconductor layer, disposed on the substrate;
a graded layer, disposed on the first semiconductor layer, wherein the graded layer is made from materials comprising a first material and a second material, the graded layer comprises at least one thin film, one of the at least one thin film comprises a mixture of at least the first material and the second material at a mixture ratio, and the mixture forms a bandgap of the at least one thin film; and
a second semiconductor layer disposed on the graded layer.

15. The structure of the solar cell according to claim 14, wherein the graded layer comprises a plurality of thin films with a plurality of corresponding bandgaps of the thin films, each thin film comprises a mixture of the first material and the second material at a corresponding mixture ratio, and the mixtures form the corresponding bandgaps of the thin films.

16. The structure of the solar cell according to claim 15, wherein the first semiconductor layer is made from a low bandgap semiconductor material, the second semiconductor layer is made from a high bandgap semiconductor material, and the graded layer including the thin films has a graded bandgap increasing with distance away from the first semiconductor layer towards the second semiconductor layer.

17. The structure of the solar cell according to claim 15, wherein the first semiconductor layer is made from a high bandgap semiconductor material, the second semiconductor layer is made from a low bandgap semiconductor material, and the graded layer including the thin films has a graded bandgap decreasing with distance away from the first semiconductor layer towards the second semiconductor layer.

18. The structure of the solar cell according to claim 14, wherein the first semiconductor layer is made from a low bandgap semiconductor material, the second semiconductor layer is made from a high bandgap semiconductor material, and the graded layer is made from the materials whose bandgap is greater than that of the first semiconductor layer and less than that of the second semiconductor layer.

19. The structure of the solar cell according to claim 14, wherein the first semiconductor layer is made from a high bandgap semiconductor material, the second semiconductor layer is made from a low bandgap semiconductor material, and the graded layer is made from the materials whose bandgap is less than that of the first semiconductor layer and greater than that of the second semiconductor layer.

20. The structure of the solar cell according to claim 14, wherein one of the first and second semiconductor layers is made from a low bandgap semiconductor material, the other of the first and second semiconductor layers is made from a high bandgap semiconductor material.

21. The structure of the solar cell according to claim 14, wherein the graded layer comprises a plurality of thin film groups, each thin film group corresponds to a bandgap.

22. The structure of the solar cell according to claim 21, wherein the first semiconductor layer is made from a high bandgap semiconductor material, the second semiconductor layer is made from a low bandgap semiconductor material, and the graded layer including the thin films has a bandgap alternating between high and low bandgap levels and substantially decreasing away from the first semiconductor layer towards the second semiconductor layer.

23. The structure of the solar cell according to claim 21, wherein the first semiconductor layer is made from a low bandgap semiconductor material, the second semiconductor layer is made from a high bandgap semiconductor material, and the graded layer including the thin films has a bandgap alternating between high and low bandgap levels and substantially increasing away from the first semiconductor layer towards the second semiconductor layer.

24. The structure of the solar cell according to claim 14, further comprising:
a first electrode, disposed on a portion of the second semiconductor layer; and
a second electrode, disposed on a portion of an upper surface of the first semiconductor layer.

25. The structure of the solar cell according to claim 14, wherein the first material is made from a metal oxide or semiconductor material, the second material is made from a metal oxide or semiconductor material, and the first and the second materials are of different bandgaps.

26. The structure of the solar cell according to claim 25, wherein the metal oxide material comprises at least one of titanium dioxide (TiO₂), indium oxide (InO), indium tin oxide (ITO), manganese oxide (MgO), tin dioxide (SnO₂), germanium dioxide (GeO₂), aluminum oxide (Al₂O₃), tantalum oxide (TaO₅), cupric oxide (CuO), and zirconium dioxide (ZrO₂).
